(19) United States
(12) Patent Application Publication
(10) Pub. No.: US 2015/0262963 A1
(43) Pub. Date: Sep. 17, 2015

(54) SEMICONDUCTOR DEVICE AND WIRE BONDING INTERCONNECTION METHOD

(71) Applicant: Panasonic Intellectual Property Management Co., Ltd., Osaka (JP)

(72) Inventors: Kenichi KOYA, Kagoshima (JP); Isamu YONEKURA, Kagoshima (JP); Daisuke FUKAMACHI, Kagoshima (JP); Shinya HARANO, Kagoshima (JP)

(21) Appl. No.: 14/724,661

(22) Filed: May 28, 2015

Related U.S. Application Data
(63) Continuation of application No. PCT/JP2013/006818, filed on Nov. 20, 2013.

(30) Foreign Application Priority Data
Nov. 28, 2012 (JP) 2012-259348

(51) Int. Cl. H01L 23/00

(52) U.S. Cl. CPC H01L 24/48; H01L 24/85; H01L 2224/45139; H01L 2224/48227; H01L 2224/4845; H01L 2224/48465; H01L 2224/48482; H01L 2224/78301; H01L 2224/85051; H01L 2924/12041

(57) ABSTRACT

A first bond portion is formed on a first electrode, and for a wire extended from the first bond portion, a tip of a capillary is pressed against a bump formed on a second electrode, to form a second bond portion to which a shape of a pressing surface at the tip of the capillary is transferred. A base end of the second bond portion from which the wire starts becoming thinner is located on the inside of the bump from an end of a bonding surface by 10% or more of the length of the bonding surface, and the wire is cut with the capillary.

### CROSS-REFERENCE TO RELATED APPLICATIONS

This is a continuation of International Application No. PCT/JP2013/006818 filed on Nov. 20, 2013, which claims priority to Japanese Patent Application No. 2012-259348 filed on Nov. 28, 2012. The entire disclosures of these applications are incorporated by reference herein.

### BACKGROUND

The present disclosure relates to a semiconductor device where electrodes are connected to each other via wires and a wire bonding interconnection method.

A wire formed of a metal thin line is used to conductively connect electrodes apart from each other. After a ball bump is formed on one electrode, the wire is extended from the other electrode to the ball bump. As techniques related to such wire interconnection, those described in International Patent Publication No. WO2010/005086 (Patent Document 1) and Japanese Unexamined Patent Publication No. 2008-235849 (Patent Document 2) are known.

Patent Document 1 describes a bonding structure of a bonding wire, where the bonding wire and a ball bump are made of copper as a main ingredient, an increased concentration layer having a concentration of metal other than copper of ten times or more the average concentration of the metal of the ball bump is provided at the bonding interface, and an increased concentration layer having a concentration of metal of ten times or more the average concentration of the metal of the ball bump is provided at the bonding interface between the ball bump and an electrode.

Patent Document 2 describes a semiconductor device and a wiring bonding method, where a wire is bent in layers at a second bond point to form a bump, the wire is looped toward the bump and pressed against the bump with a tip of a capillary, to bond the wire to the bump, and the wire is pressed against a first wire bent protrusion with an inner chamfer section, to form a wire crushed portion having an arc-shaped section.

The bonding structure of the bonding wire described in Patent Document 1, where copper is used as a main ingredient of the wire material, has the following problem. When the wire material is copper, or gold as generally used, the breaking load that is the load at breaking of the wire is comparatively large. Therefore, if a crushing start position for thinning the wire is located at an end of the bump at the time when the wire is wedge-bonded to an inclined surface of the bump, the crushed cross-section will not be thinned. When the capillary is pulled up, therefore, the wire will not be cut completely, but a thin line will be pulled up, stretching, from the wedge. As a result, wire bending, etc. may occur in some case.

The semiconductor device and the wire bonding method described in Patent Document 2 have the following problem. The wire is crushed on the protrusion of the bump and cut to form the wire crushed portion, thereby improving the bonding property and cutting property of the wire. In this wire bonding method, however, since the tip portion of the wedge is near the center of the top surface of the bump, the crushing start position (wedge starting point) is conversely too close to the bump end, resulting in failing to bond the wire to the bump using a thick portion of the wire where stronger bonding therebetween can be obtained.

In a semiconductor device, a wire that connects electrodes to each other is sealed with a resin. If the semiconductor device is subjected to heating, the wire connected to a bump may come off, or the connecting portion of the bump may be broken, due to a difference in thermal expansion between the wire formed of a metal thin line and the sealing resin. Therefore, the wire is required to have high bonding property to the bump.

### SUMMARY

An objective of the present disclosure is providing a semiconductor device, and a wire bonding method, where the reliability can be improved by improving the bonding property and cutting property of wires.

According to an aspect of the disclosure, a semiconductor device includes at least one wire that conductively connects a first electrode and a second electrode on which a bump is formed, wherein the wire is formed of an alloy having silver as a main material, and has a first bond portion formed at a junction with the first electrode and a second bond portion formed at a junction with the bump on the second electrode, the second bond portion has a tapered shape, and a base end of the second bond portion from which the wire starts becoming thinner is located on a bonding surface between the wire and the bump as viewed from top, and the length of the wire from an end of the bonding surface on the side closer to the first bond portion to the base end is 10% or more of the length of the bonding surface in a direction in which the wire extends.

According to another aspect of the disclosure, a wire bonding interconnection method for conductively connecting a first electrode and a second electrode via a wire formed of an alloy having silver as a main material in a semiconductor device is provided. The method includes the steps of: (1) forming a first bond portion by extruding a metal material from a feed port at a tip of a capillary and pressing the metal material against the first electrode; (2) forming a wire loop by moving the capillary toward the second electrode while extruding the metal material from the feed port; and (3) forming a second bond portion by pressing the tip of the capillary against a bonding surface of a bump formed on the second electrode, wherein in step (3), the shape of a pressing surface at the tip of the capillary is transferred to the second bond portion to give a tapered shape to the second bond portion, and the position of the capillary is controlled so that a base end from which the wire starts becoming thinner is located on the bonding surface as viewed from top, and the length of the wire from an end of the bonding surface on the side closer to the first bond portion to the base end is 10% or more of the length of the bonding surface in a direction in which the wire extends.

According to the disclosure, since the second bond portion and the bonding surface of the bump can be bonded to each other firmly, the durability against a difference in thermal expansion between the sealing section made of resin and the wire made of metal can be improved. Thus, with the bonding property and the cutting property being improved, the reliability can be improved.

### BRIEF DESCRIPTION OF THE DRAWINGS

FIGS. 1A and 1B are a plan view and a front view, respectively, showing a light emitting device according to an embodiment.

FIGS. 2A-2C are views explaining steps of wire bonding of a wire that conductively connects a light emitting element and a lead frame of the light emitting device shown in FIG. 1, showing a state where a bump is formed, a state where the wire is being extended toward the bump after formation of a first bond portion, and a state where a second bond portion is formed on the bump to complete the interconnection, respectively.

FIGS. 3A and 3B are enlarged views for explaining states at the formation of the second bond portion, showing a state where a wedge starting point is located at a lower-limit point and a state where the wedge starting point is located at an upper-limit point, respectively.

FIG. 4 is a view showing simulation results of equivalent stress and thermal shock test results for each position of the wedge starting point.

FIGS. 5A and 5B are views showing results of measurement of breaking load performed based on the diameter of the wire, the material of the wire, and the temperature, where the diameter of the wire is 23 μm and 25 μm, respectively.

FIGS. 6A and 6B are a plan view and a front view, respectively, showing an example of a light emitting device having two light emitting elements placed on an anode terminal.

FIGS. 7A and 7B are a plan view and a front view, respectively, showing an example of a light emitting device having one light emitting element placed on a cathode terminal and one light emitting element placed on an anode terminal.

### DETAILED DESCRIPTION

According to a first aspect of the disclosure, a semiconductor device includes at least one wire that conductively connects a first electrode and a second electrode on which a bump is formed, wherein the wire is formed of an alloy having silver as a main material, and has a first bond portion formed at a junction with the first electrode and a second bond portion formed at a junction with the bump on the second electrode, the second bond portion has a tapered shape, and a base end of the second bond portion from which the wire starts becoming thinner is located on a bonding surface between the wire and the bump as viewed from top, and the length of the wire from an end of the bonding surface on the side closer to the first bond portion to the base end is 10% or more of the length of the bonding surface in a direction in which the wire extends.

According to the first aspect, since the wire is formed of an alloy having silver as a main material, the breaking load can be small compared with the cases of using copper and gold. Also, since the second bond portion has a tapered shape, and the base end from which the wire starts becoming thinner is located on the inside of the bump by 10% or more with respect to the length of the bonding surface in the wire extending direction, a large-diameter portion of the wire is allowed to stay on the bonding surface of the bump over a sufficient length. Thus, since the tip portion of the wire including the second bond portion and the bonding surface of the bump can be bonded to each other firmly, the durability against a difference in thermal expansion between the sealing section made of resin and the wire made of metal can be improved. Accordingly, since the bonding property and cutting property of the wire can be improved, the reliability of the semiconductor device can be improved.

According to a second aspect of the disclosure, the semiconductor device in the first aspect further includes a semiconductor element and a first lead electrode, wherein the wire includes a first wire that conductively connects the first lead electrode as the first electrode and a first element electrode, as the second electrode, formed on a top surface of the semiconductor element and located at a position higher than the first lead electrode.

According to the second aspect, since the wire is extended from the first lead electrode at a low position to the element electrode of the semiconductor element at a high position, a low loop low in wire interconnection height can be achieved.

According to a third aspect of the disclosure, the semiconductor device in the second aspect further includes a second lead electrode, wherein the semiconductor element is placed on the second lead electrode and has a pair of element electrodes including the first element electrode formed on the top surface, and the wire includes a second wire that conductively connects the second lead electrode as the first electrode and one of the pair of element electrodes of the semiconductor element that is not connected to the first wire, as the second electrode.

According to the third aspect, it is possible to provide a semiconductor device where wires are extended from a pair of element electrodes of the semiconductor element placed on the second lead electrode to the first lead electrode and the second lead electrode.

According to a fourth aspect of the disclosure, the semiconductor device in the first aspect further includes first and second semiconductor elements, wherein the wire includes a first wire that conductively connects an element electrode formed on a top surface of the first semiconductor element as the first electrode and an element electrode formed on a top surface of the second semiconductor element and located at the same height as the element electrode on the first semiconductor element, as the second electrode.

According to the fourth aspect, the bonding property of the wire can be improved even when the element electrodes of the first and second semiconductor elements are at the same height.

According to a fifth aspect of the disclosure, the semiconductor device in the fourth aspect further includes first and second lead electrodes, wherein each of the first and second semiconductor elements is placed on the second lead electrode and has a pair of element electrodes including the element electrode formed on the top surface, and the wire includes a second wire that conductively connects the first lead electrode as the first electrode and one of the pair of element electrodes of the first semiconductor element that is not connected to the first wire, as the second electrode, and a third wire that conductively connects the second lead electrode as the first electrode and one of the pair of element electrodes of the second semiconductor element that is not connected to the first wire, as the second electrode.

According to the fifth aspect, in the semiconductor device where the first and second semiconductor elements are placed on the second lead electrode, the bonding property can be improved for the second wire that connects the first lead electrode and the element electrode of the first semiconductor element and the third wire that connects the second lead electrode and the element electrode of the second semiconductor element, in addition to the wire that connects the element electrode of the first semiconductor element and the element electrode of the second semiconductor element.

According to a sixth aspect of the disclosure, the semiconductor device in the fourth aspect further includes first and second lead electrodes, wherein the first semiconductor element is placed on the first lead electrode and has a pair of element electrodes including the element electrode formed on the top surface, the second semiconductor element is placed on the second lead electrode and has a pair of element electrodes including the element electrode formed on the top surface, and the wire includes a second wire that conductively connects the first lead electrode as the first electrode and one of the pair of element electrodes of the first semiconductor element that is not connected to the first wire, as the second electrode, and a third wire that conductively connects the second lead electrode as the first electrode and one of the pair of element electrodes of the second semiconductor element that is not connected to the first wire, as the second electrode.

According to the sixth aspect, in the semiconductor device where the first semiconductor element is placed on the first lead electrode and the second semiconductor element is placed on the second lead electrode, the bonding property can be improved for the second wire that connects the first lead electrode and the element electrode of the first semiconductor element and the third wire that connects the second lead electrode and the element electrode of the second semiconductor element, in addition to the wire that connects the element electrode of the first semiconductor element and the element electrode of the second semiconductor element.

According to a seventh aspect of the disclosure, a wire bonding interconnection method for conductively connecting a first electrode and a second electrode via a wire formed of an alloy having silver as a main material in a semiconductor device is provided. The method includes the steps of: (1) forming a first bond portion by extruding a metal material from a feed port at a tip of a capillary and pressing the metal material against the first electrode; (2) forming a wire loop by moving the capillary toward the second electrode while extruding the metal material from the feed port; and (3) forming a second bond portion by pressing the tip of the capillary against a bonding surface of a bump formed on the second electrode, wherein in step (3), the shape of a pressing surface at the tip of the capillary is transferred to the second bond portion to give a tapered shape to the second bond portion, and the position of the capillary is controlled so that a base end from which the wire starts becoming thinner is located on the bonding surface as viewed from top, and the length of the wire from an end of the bonding surface on the side closer to the first bond portion to the base end is 10% or more of the length of the bonding surface in a direction in which the wire extends.

According to the seventh aspect, since the wire is formed of an alloy having silver as a main material, the breaking load can be small compared with the cases of using copper and gold. Also, since the position of the capillary is controlled so that the second bond portion has a tapered shape, and that the base end from which the wire starts becoming thinner is located on the inside of the bump by 10% or more with respect to the length of the bonding surface in the wire extending direction, a large-diameter portion of the wire is allowed to stay on the bonding surface of the bump over a sufficient length. Thus, since the tip portion of the wire including the second bond portion and the bonding surface of the bump can be bonded to each other firmly, the durability against a difference in thermal expansion between the sealing section made of resin and the wire made of metal can be improved. Accordingly, since the bonding property and cutting property of the wire can be improved, the reliability of the semiconductor device can be improved.

According an eighth aspect of the disclosure, in step (3) in the seventh aspect, the position of the capillary is controlled so that an edge of the feed port at the tip of the capillary does not come off the bonding surface.

According to the eighth aspect, the tip of the second bond portion of the wire can be cut on the bonding surface to form the wire.

### Embodiment

A semiconductor device according to an embodiment will be described with reference to the accompanying drawings, taking a light emitting device as an example.

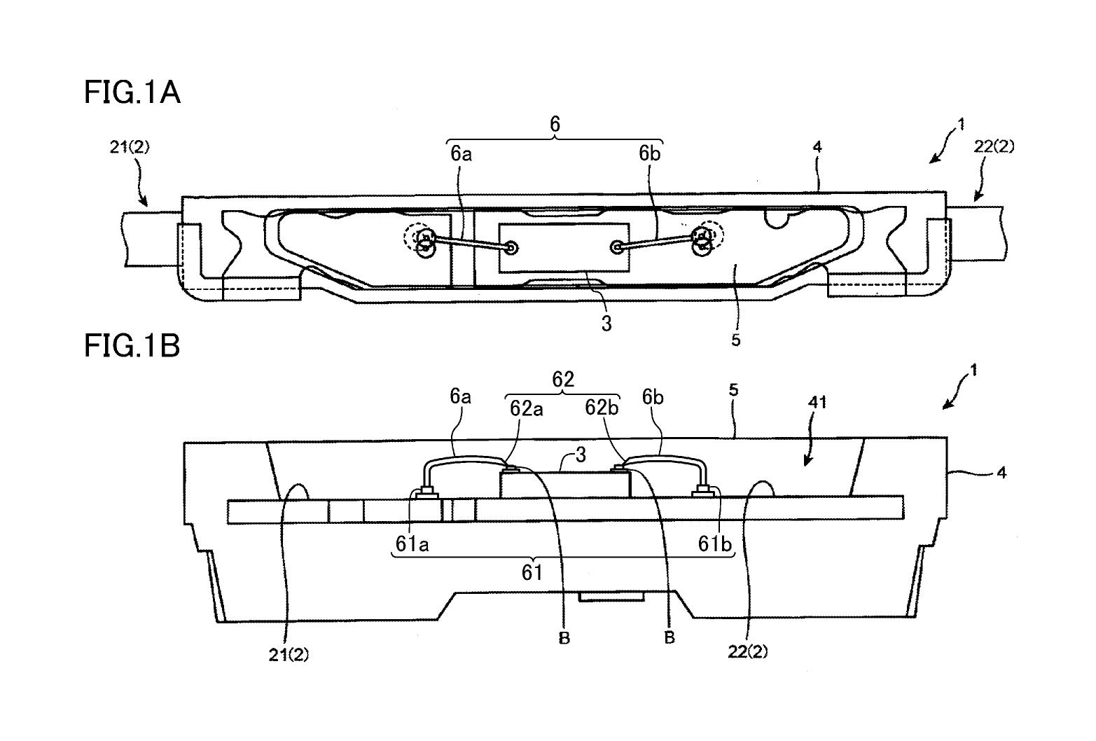

A light emitting device 1 shown in FIGS. 1A and 1B includes a lead frame 2 as a base, a light emitting element 3 as an example of a semiconductor element, a package section 4, and a sealing section 5.

The lead frame 2, formed of a metal sheet, is comprised of a cathode terminal (first lead electrode) 21 and an anode terminal (second lead electrode) 22. The cathode terminal 21 is conductively connected to the light emitting element 3 via a wire 6a, and the anode terminal 22 is conductively connected to the light emitting element 3 via a wire 6b. In the following description, the wires 6a and 6b are collectively referred to as the wires 6 in some cases.

As the light emitting element 3, a blue light emitting diode (LED), a red LED, a green LED, etc. may be used appropriately according to the use. The light emitting element 3 is an LED where semiconductor layers are formed on an insulating substrate, and an n-side electrode that is to be a cathode and a p-side electrode that is to be an anode are formed on the top surface as a pair of element electrodes. The n-side electrode is formed on an n-type semiconductor layer exposed by etching a light emitting layer, a p-type semiconductor layer, and part of the n-type semiconductor layer, and the p-side electrode is formed on a region of the p-type semiconductor layer remaining unetched at the formation of the n-side electrode. The wires 6 are connected to the n-side electrode and the p-side electrode formed on the top surface. The n-side electrode and the p-side electrode are hereinafter referred to as the electrode pads in some cases.

The package section 4 has a recess 41 to form the sealing section 5 therein. The package section 4 is formed to expose surface portions of the cathode terminal 21 and anode terminal 22 of the lead frame 2 as bond portions for the wires 6 and spread over the cathode terminal 21 and the anode terminal 22. The package section 4 can be formed of a resin material such as epoxy resin and silicone resin.

The sealing section 5 is formed in the recess 41 of the package section 4 to seal the light emitting element 3 and the wires 6. In the sealing section 5, a phosphor that is excited with light from the light emitting element 3 and changes the wavelength of the light can be contained in a transparent medium that is a main material such as a resin or glass. Assume, for example, that the light emitting element 3 emits blue color. By putting into the sealing section 5 a phosphor that emits yellow light, the blue light from the light emitting element 3 and the yellow light from the phosphor will be mixed, to obtain white light. As the phosphor, a silicate phosphor and a YAG phosphor can be used.

The wires 6 are interconnections for supplying power supply fed to the lead frame 2 from outside to the light emitting element 3. The wires 6 are formed of an alloy having silver as a main material. This alloy includes one kind or two or more kinds of metal out of Cu, Pt, Pd, Ru, Os, Rh, Ir, Ca, Sr, Y, La, Ce, Eu, Be, Ge, In, and Sn, for example in an amount of 10% by weight or less, or can contain Au.

The wire 6a as the first wire conductively connects the cathode element 21 as the first electrode and the n-type electrode as the second electrode formed on the top surface of the light emitting element 3. The wire 6a has a first bond portion 61a formed at the junction with the cathode element 21 and a second bond portion 62a formed at the junction with a bump B on the n-type electrode of the light emitting element 3. The wire 6b as the second wire conductively connects the anode element 22 as the first electrode and the p-type electrode as the second electrode formed on the top surface of the light emitting element 3. The wire 6b has a first bond portion 61b formed at the junction with the anode element 22 and a second bond portion 62b formed at the junction with a bump B on the p-type electrode of the light emitting element 3. In the following description, the first bond portions 61a and 61b are collectively referred to as the first bond portions 61, and the second bond portions 62a and 62b are collectively referred to as the second bond portions 62, in some cases.

A wire bonding interconnection method for the wires 6 will be described hereinafter with reference to the relevant drawings. Here, the case of forming the wire 6a that conductively connects the cathode element 21 and the n-side electrode of the light emitting element 3 will be described as an example. For the case of forming the wire 6b that conductively connects the anode element 22 and the p-side electrode of the light emitting element 3, also, a similar method may be employed.

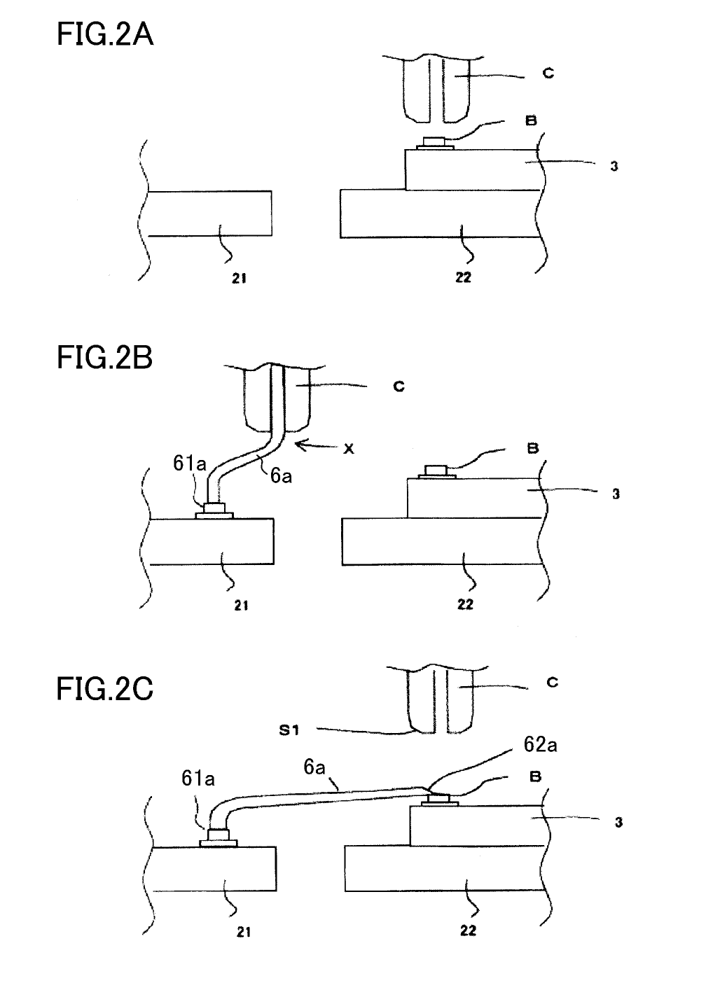

First, as shown in FIG. 2A, a capillary C is lowered to the n-side electrode of the light emitting element 3, to form the bump B.

Thereafter, the capillary C is raised, and after being horizontally moved to a position above the cathode terminal 21, lowered to the top surface of the cathode terminal 21. A metal material of the wire is then extruded from a feed port X at the tip of the capillary C and pressed against the cathode terminal 21, to form the first bond portion 61a. Subsequently, while the metal material is being pushed out from the feed port X to form the wire 6a, the capillary C is raised and moved toward the anode terminal 22, whereby, as shown in FIG. 2B, a wire loop is formed.

The tip of the capillary C is then moved to the bump B and pressed against the bonding surface of the bump B. With this, the tip of the wire 6a is crushed between a pressing surface S1 formed on an arc surface surrounding the feed port of the capillary C and the bump B, with the shape of the pressing surface S1 at the tip of the capillary C being transferred to the tip portion of the wire 6a. The crushed tip of the wire 6a forms the second bond portion 62a. In this way, the wire 6a is bonded to the bonding surface of the bump B to complete interconnection.

In the second bond portion 62a of the wire 6a, to which the shape of the pressing surface S1 at the tip of the capillary C is transferred, the cross-section of the wire body having a uniform thickness changes into an inwardly-bent arc shape gradually becoming thinner from the base end, to be described later, toward the tip. That is, the second bond portion 62a has a tapered shape.

Thus, since the wire 6a is extended from the cathode terminal 21 at a low position to the n-side electrode formed on the top surface of the light emitting element 3 at a position higher than the cathode terminal 21, the low-loop wire 6a low in interconnection height can be formed. Also, since the wire 6b is extended from the anode terminal 22 at a low position to the p-side electrode formed on the top surface of the light emitting element 3 at a position higher than the anode terminal 22, the low-loop wire 6b low in interconnection height can be formed in a similar manner.

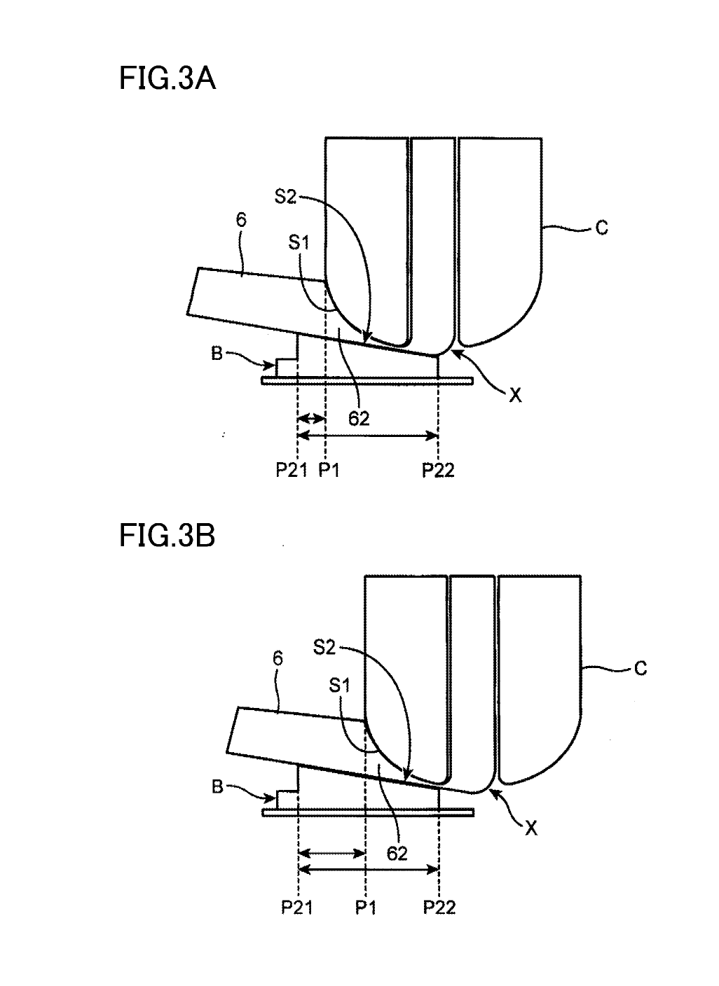

Next, referring to FIGS. 3A and 3B, the relationship in shape between the tip of the wire 6 and the bonding surface of the bump B will be described.

As shown in FIG. 3A, a wedge starting point P1 that is to be the base end of the second bond portion 62 from which the wire 6 starts becoming gradually thinner is located inside the range of a bonding surface S2 of the bump B beyond one end P21 of the bonding surface S2. In other words, the wedge starting point P1 lies on the bonding surface S2 as viewed from top.

It is desirable that the degree of entering of the wedge starting point P1 into the range of the bonding surface S2 be 10% or more, e.g., 15% or more, with respect to the length of the bonding surface S2 of the bump B in the interconnection direction. In other words, it is desirable that the length of the wire 6 from the one end P21 of the bonding surface S2 to the wedge starting point P1 in the direction in which the wire 6 extends be 10% or more of the length of the bonding surface S2. By this setting, the base end of the second bond portion 62 (wedge starting point P1) from which the thickness of the wire 6 becomes gradually thinner is brought toward the other end P22 of the bonding surface S2. This allows a large-diameter portion of the wire 6 to stay on the bonding surface S2 of the bump B over a sufficient length. Therefore, since the tip portion of the wire 6 including the second bond portion 62 can be bonded to the bonding surface S2 of the bump B firmly, the durability against a difference in thermal expansion between the sealing section 5 made of resin and the wire 6 made of metal can be improved. Thus, the reliability of the low-loop wire 6 can be improved.

It is also desirable to set the degree of entering of the wedge starting point P1 inside the range of the bonding surface S2 to 20% or more with respect to the length of the bonding surface S2 of the bump B in the interconnection direction, because, by this setting, the durability can be significantly improved even under an environment where the temperature sharply changes.

It is desirable to control the position of the wedge starting point P1 on the bonding surface S2 of the bump B so that the edge of the feed port X on the pressing surface S1 of the capillary C does not come off the bonding surface S2 of the bump B, that is, does not cross over the other end P22 of the bonding surface S2 of the bump B, as shown in FIG. 3B. By this control, the second bond portion 62 can be formed by cutting the tip of the wire 6 at a position on the bonding surface S2.

In this embodiment, since the contour shape of the bonding surface S2 of the bump B is roughly circular, the length of the bonding surface S2 in the interconnection direction corresponds with the diameter of the bump B. In an example of this embodiment, the diameter of the bump B is set to about 80 μm and the length from the one end P21 of the bonding surface S2 of the bump B to the wedge starting point P1 is set to about 16 μm. In this case, the percentage of the length from the one end P21 of the bonding surface S2 of the bump B to the wedge starting point P1 with respect to the diameter of the bump B is about 20%.

Simulation was performed to examine the thermal stress of the light emitting device 1 according to this embodiment. In the simulation, equivalent stresses exerted on the second bond portion 62 due to shrinkage/extension of the wire 6 and contraction/expansion of the sealing section 5 were calculated at temperatures of −45° C. and +125° C. using a silver alloy having a purity of 95% as the wire 6 and a silicone resin having a Young's modulus of 15 MPa and a Poisson's ratio of 0.49 as the sealing section 5. The calculated values are relative values.

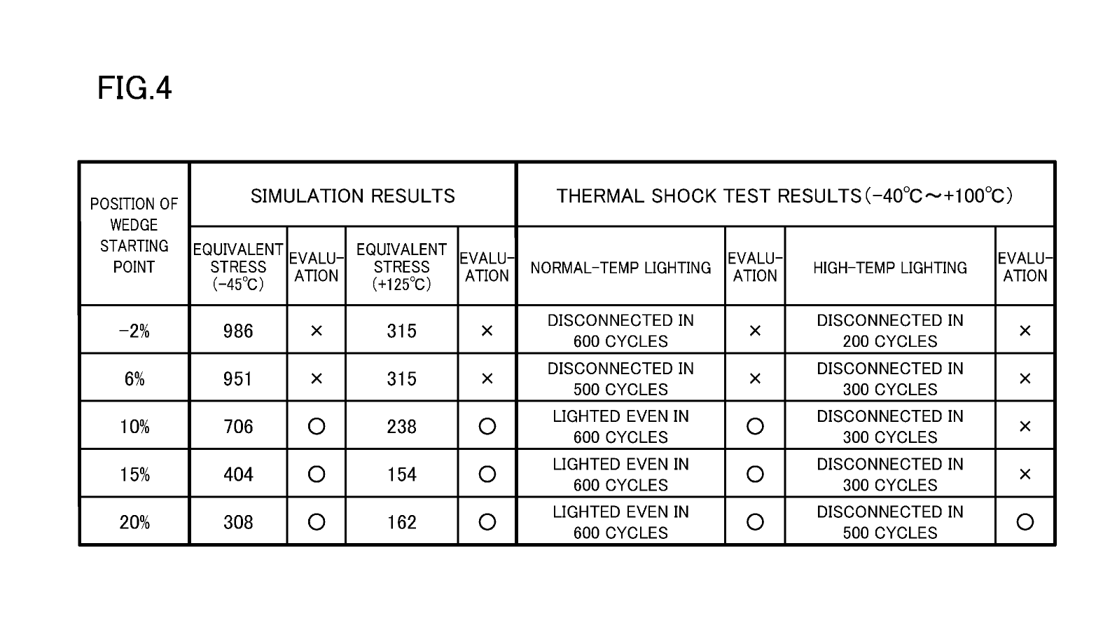

As a result of the simulation, as shown in FIG. 4, it is found that the equivalent stress is largely reduced when the wedge starting point P1 is set to 10%, 15%, and 20% located on the bump B, compared with when it is set to −2% located before reaching the bump B and to 6% located on the bump B, for both −45° C. and +125° C. Therefore, it is desirable that the wedge starting point is at a position on the bump B by 10% or more.

A thermal shock test was then executed by actually manufacturing the light emitting device 1 for which the simulation was performed. In the thermal shock test, a temperature change from −40° C. to 100° C. as one cycle was repeated, and the lighting condition was tested in a normal-temperature state (25° C.) and a high-temperature state (100° C.) every 100 cycles. The reason why the lighting condition is tested in two states of a normal-temperature state and a high-temperature state is to check the bonded state of the wire 6 reliably. For example, there is a case where the second bond portion 62 comes off the bump B but still in contact with the bump B. In this case, since the light emitting element 3 lights up, it is unable to ascertain that the second bond portion 62 is off the bump B. In a high-temperature state, the resin of the sealing section 5 thermally expands causing the wire 6 to easily stand out against the bump B. Thus, it becomes easy to ascertain that the second bond portion 62 is off compared with in a normal-temperature state. Accordingly, the test is performed in two state of a high-temperature state and a normal-temperature state.

As shown in FIG. 4, when the wedge starting point was set to −2% located before reaching the bump B, disconnection of the wire 6 was ascertained at 600 cycles for normal-temperature lighting and at 200 cycles for high-temperature lighting. When the wedge starting point was set to 6%, disconnection of the wire 6 was ascertained at 500 cycles for normal-temperature lighting and at 300 cycles for high-temperature lighting. When the wedge starting point was set to 10%, while lighting was observed even at 600 cycles for normal-temperature lighting, disconnection of the wire 6 was ascertained at 300 cycles for high-temperature lighting. When the wedge starting point was set to 15%, while lighting was observed even at 600 cycles for normal-temperature lighting, disconnection of the wire 6 was ascertained at 300 cycles for high-temperature lighting. When the wedge starting point was set to 20%, while lighting was observed even at 600 cycles for normal-temperature lighting, disconnection of the wire 6 was ascertained at 500 cycles for high-temperature lighting.

Accordingly, from the standpoint of thermal shock, it is desirable to set the wedge starting point P1 to 20% or more.

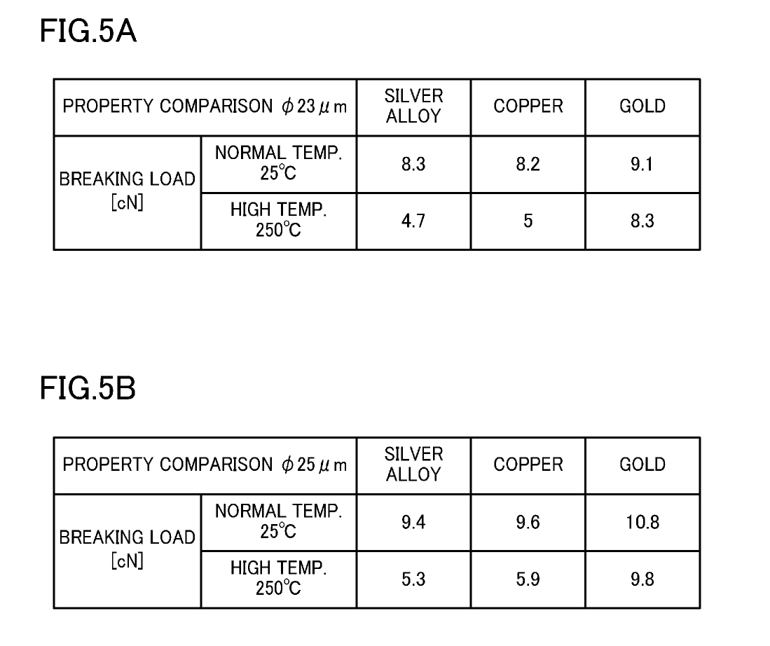

Next, referring to FIGS. 5A and 5B, the breaking load of the wire 6 will be described.

In this embodiment, the wire 6 is formed of silver as a main material. FIGS. 5A and 5B show examples of measurement values of breaking load observed in the cases where the wire is made of a silver alloy, copper, and gold. The thickness (diameter) of the wire is 23 μm in FIG. 5A and 25 μm in FIG. 5B. Also, the measurement values show the results obtained when a tensile test is performed at a normal temperature of 25° C. and when a tensile test is performed after heating at a high temperature of 250° C. for 20 seconds.

As shown in FIG. 5A, when the diameter of the wire is 23 μm, while the silver alloy exhibits a breaking load value slightly higher than copper at 25° C., it exhibits a value lower than gold and copper at 250° C. Also, as shown in FIG. 5B, when the diameter of the wire is 25 μm, the silver alloy exhibits values lower than gold and copper at both 25° C. and 250° C. Therefore, by using a silver alloy as the wire 6, the wire 6 can be easily cut when the second bond portion 62 of the wire 6 is formed and cut. While a silver alloy having a purity of 95% was used as the wire 6 and a silicone resin as the sealing section 5 in the examples shown in FIGS. 4, 5A, and 5B, it is considered to obtain a similar tendency when the wire 6 is made of a silver alloy having silver as a main material and the sealing section 5 is made of a resin or made of glass different in expansion coefficient.

As described above, according to this embodiment, since the bonding property and cutting property of the wire 6 can be improved, the reliability of the light emitting device 1 can be improved.

In the silver alloy having a diameter of 25 μm, the cutting property is also good when an Ag line is used, which has a breaking load of 8 cN, smaller than gold having 9.8 cN, as the result of the tensile test performed after heating at a high temperature of 250° C. for 20 seconds. The reason is that silver is generally higher in free-cutting property than gold, and an Ag alloy, containing silver as a main material, is also higher in cutting property than gold.

Moreover, by using a silver alloy having an Ag purity of 94% or more, the amount of one kind or two or more kinds of metal out of Cu, Pt, Pd, Ru, Os, Rh, Ir, Ca, Sr, Y, La, Ce, Eu, Be, Ge, In, and Sn, included in the wire 6 increases. Therefore, the bonding property enhances in the thermal shock test of −40° C. to 100° C., etc. Also, with the silver purity being high, the reflectivity enhances, permitting implementation of a high-brightness light emitting device. Thus both high brightness and high reliability can be achieved.

### Other Configuration Examples

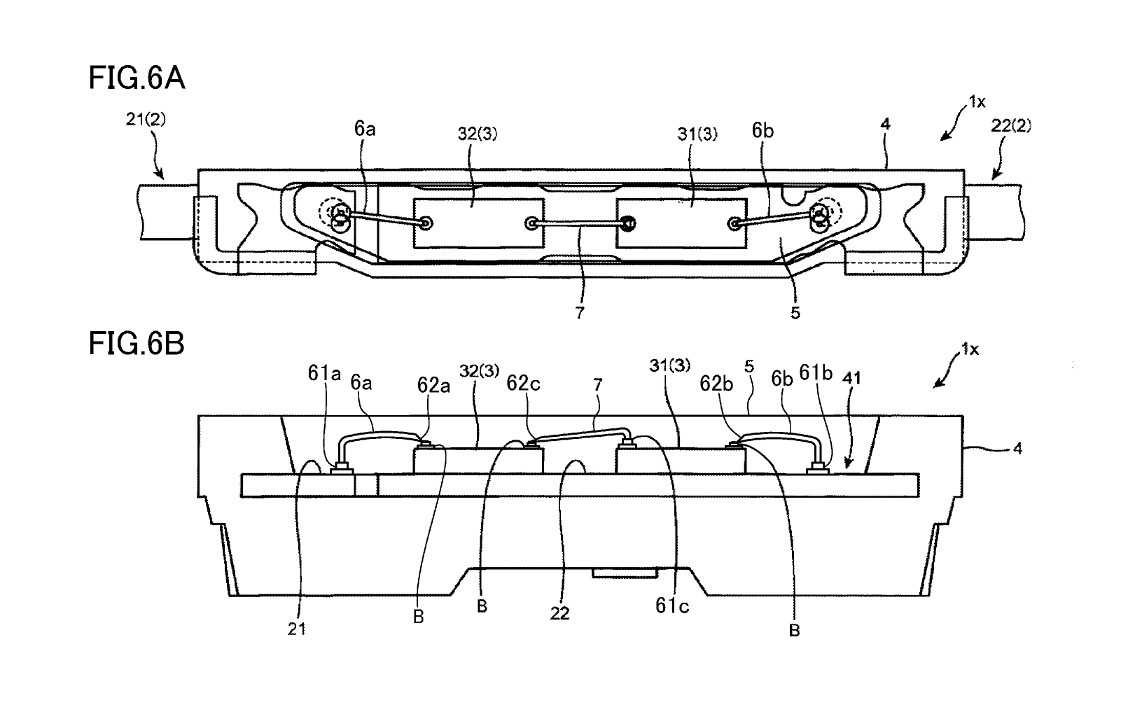

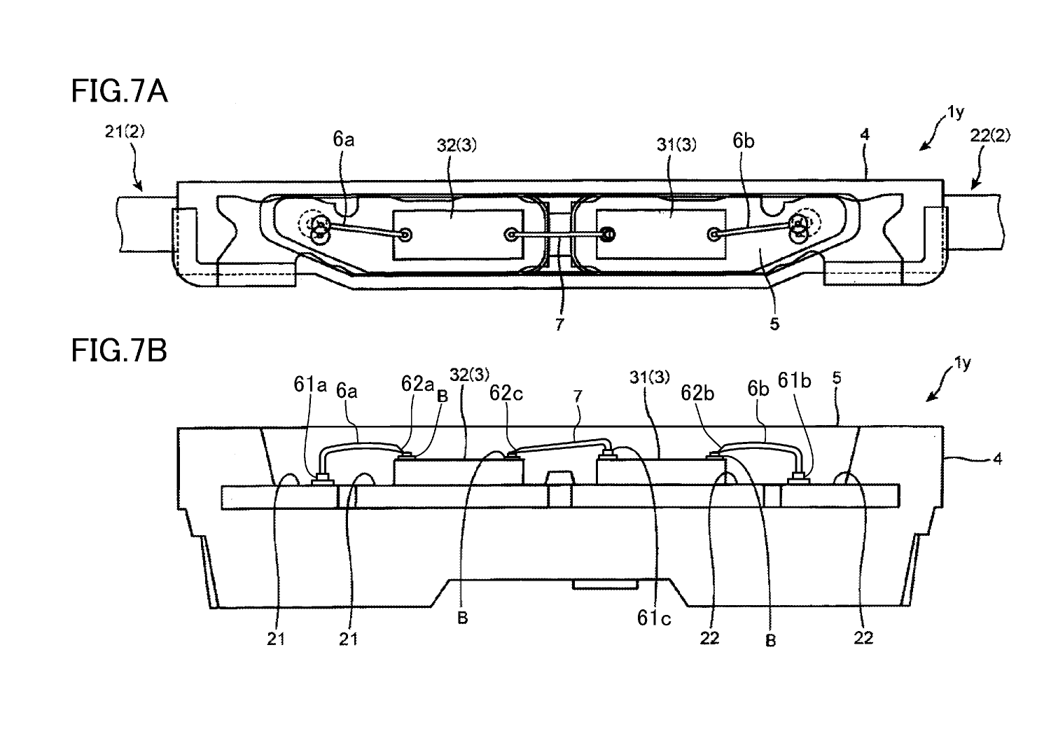

In the light emitting device 1 shown in FIG. 1, the lead frame 2 and the light emitting element 3 are conductively connected via the wires 6. In each wire 6, the first bond portion 61 formed at the junction with the lead frame 2 is located at a low position, and the second bond portion 62 formed at the junction with the bump B on the electrode of the light emitting element 3 is located at a high position. However, the wire in this embodiment can also be used in a configuration other than the configuration shown in FIG. 1, such as configurations of light emitting devices shown in FIGS. 6 and 7, for example. Note that, in FIGS. 6 and 7, components used in common with FIG. 1 are denoted by the same reference numerals, and description of such components is omitted in some cases.

A light emitting device 1x shown in FIG. 6 has two light emitting elements 3, i.e., a first light emitting element 31 as the first semiconductor element and a second light emitting element 32 as the second semiconductor element formed on an anode terminal (second lead electrode) 22. A wire 6a is connected from a cathode terminal (first lead electrode) 21 to an n-side electrode as one electrode of the second light emitting element 32, and a wire 6b is connected from the anode terminal 22 to a p-side electrode as one electrode of the first light emitting element 31. Further, a wire 7 is connected from an n-side electrode as the other element electrode of the first light emitting element 31 to a p-side electrode as the other element electrode of the second light emitting element 32.

The wire 7 as the first wire has a first bond portion 61c formed at the junction with the n-side electrode of the first light emitting element 31 and a second bond portion 62c formed at the junction with the p-side electrode of the second light emitting element 32. That is, the wire 7 connects the electrodes at the same height to each other. The wire 7 has the same configuration as the wires 6a and 6b as the second and third wires. That is, the second bond portion 62c has a tapered shape, and the position of the wedge starting point from which the wire 7 starts becoming thinner is located on the inside of the bump B from one end of a bonding surface of a bump B formed on the p-side electrode of the second light emitting element 32 by 10% or more of the length of the bonding surface in the direction in which the wire 7 extends.

As described above, in the light emitting device 1x having two light emitting elements 3 mounted on the anode terminal 22, even for the wire 7 that connects the light emitting elements 3 to each other, the bonding strength between the wire 7 and the bump B can be improved by locating the wedge starting point on the inside of the bump B by 10% or more with respect to the length of the bonding surface of the bump B.

In a light emitting device 1y shown in FIG. 7, a first light emitting element 31 as the first semiconductor element, out of two light emitting elements 3, is placed on an anode terminal (first lead electrode) 22, and a second light emitting element 32 as the second semiconductor element is placed on a cathode terminal (second lead electrode) 21. A wire 6a is connected from the cathode terminal 21 to an n-side electrode as one electrode of the second light emitting element 32, and a wire 6b is connected from the anode terminal 22 to a p-side electrode as one electrode of the first light emitting element 31. A wire 7 is connected from an n-side electrode as the other element electrode of the first light emitting element 31 to a p-side electrode as the other element electrode of the second light emitting element 32.

The wire 7 as the first wire has a first bond portion 61c formed at the junction with the n-side electrode of the first light emitting element 31 and a second bond portion 62c formed at the junction with the p-side electrode of the second light emitting element 32. That is, the wire 7 connects the electrodes at the same height to each other. The wire 7 has the same configuration as the wires 6a and 6b as the second and third wires. That is, the second bond portion 62c has a tapered shape, and the position of the wedge starting point from which the wire 7 starts becoming thinner is located on the inside of the bump B from one end of a bonding surface of a bump B formed on the p-side electrode of the second light emitting element 32 by 10% or more of the length of the bonding surface in the direction in which the wire 7 extends.

As described above, in the light emitting device 1y having two light emitting elements 3 placed on different terminals, i.e., the first light emitting element 31 placed on the anode terminal 22 and the second light emitting element 32 on the cathode terminal 21, even for the wire 7 that connects the light emitting elements 3 to each other, the bonding strength between the wire 7 and the bump B can be improved by locating the wedge starting point on the inside of the bump B by 10% or more with respect to the length of the bonding surface of the bump B.

According to the present disclosure, since the bonding property and cutting property of the wire can be improved, the reliability of the semiconductor device can be improved. Thus, the disclosure is suitable for a semiconductor device having electrodes connected to each other via a wire and a wire bonding interconnection method.

What is claimed is:

1. A semiconductor device comprising at least one wire that conductively connects a first electrode and a second electrode on which a bump is formed, wherein
the wire is formed of an alloy having silver as a main material, and has a first bond portion formed at a junction with the first electrode and a second bond portion formed at a junction with the bump on the second electrode,
the second bond portion has a tapered shape, and
a base end of the second bond portion from which the wire starts becoming thinner is located on a bonding surface between the wire and the bump as viewed from top, and the length of the wire from an end of the bonding surface on the side closer to the first bond portion to the base end is 10% or more of the length of the bonding surface in a direction in which the wire extends.

2. The semiconductor device of claim 1, further comprising a semiconductor element and a first lead electrode, wherein
the wire includes a first wire that conductively connects the first lead electrode as the first electrode and a first element electrode, as the second electrode, formed on a top surface of the semiconductor element and located at a position higher than the first lead electrode.

3. The semiconductor device of claim 2, further comprising a second lead electrode, wherein
the semiconductor element is placed on the second lead electrode and has a pair of element electrodes including the first element electrode formed on the top surface, and
the wire includes a second wire that conductively connects the second lead electrode as the first electrode and one of the pair of element electrodes of the semiconductor element that is not connected to the first wire, as the second electrode.

4. The semiconductor device of claim 1, further comprising first and second semiconductor elements, wherein
the wire includes a first wire that conductively connects an element electrode formed on a top surface of the first semiconductor element as the first electrode and an element electrode formed on a top surface of the second semiconductor element and located at the same height as the element electrode on the first semiconductor element, as the second electrode.

5. The semiconductor device of claim 4, further comprising first and second lead electrodes, wherein
each of the first and second semiconductor elements is placed on the second lead electrode and has a pair of element electrodes including the element electrode formed on the top surface, and
the wire includes
a second wire that conductively connects the first lead electrode as the first electrode and one of the pair of element electrodes of the first semiconductor element that is not connected to the first wire, as the second electrode, and
a third wire that conductively connects the second lead electrode as the first electrode and one of the pair of element electrodes of the second semiconductor element that is not connected to the first wire, as the second electrode.

6. The semiconductor device of claim 4, further comprising first and second lead electrodes, wherein
the first semiconductor element is placed on the first lead electrode and has a pair of element electrodes including the element electrode formed on the top surface,
the second semiconductor element is placed on the second lead electrode and has a pair of element electrodes including the element electrode formed on the top surface, and
the wire includes
a second wire that conductively connects the first lead electrode as the first electrode and one of the pair of element electrodes of the first semiconductor element that is not connected to the first wire, as the second electrode, and
a third wire that conductively connects the second lead electrode as the first electrode and one of the pair of element electrodes of the second semiconductor element that is not connected to the first wire, as the second electrode.

7. A wire bonding interconnection method for conductively connecting a first electrode and a second electrode via a wire formed of an alloy having silver as a main material in a semiconductor device, the method comprising the steps of:
(1) forming a first bond portion by extruding a metal material from a feed port at a tip of a capillary and pressing the metal material against the first electrode;
(2) forming a wire loop by moving the capillary toward the second electrode while extruding the metal material from the feed port; and
(3) forming a second bond portion by pressing the tip of the capillary against a bonding surface of a bump formed on the second electrode,
wherein
in step (3), the shape of a pressing surface at the tip of the capillary is transferred to the second bond portion to give a tapered shape to the second bond portion, and
the position of the capillary is controlled so that a base end from which the wire starts becoming thinner is located on the bonding surface as viewed from top, and the length of the wire from an end of the bonding surface on the side closer to the first bond portion to the base end is 10% or more of the length of the bonding surface in a direction in which the wire extends.

8. The wire bonding interconnection method of claim 7, wherein, in step (3), the position of the capillary is controlled so that an edge of the feed port at the tip of the capillary does not come off the bonding surface.
